(19) United States
(12) Patent Application Publication
(10) Pub. No.: US 2023/0256664 A1
(43) Pub. Date: Aug. 17, 2023

(54) IMPRINT APPARATUS, FOREIGN PARTICLE REMOVAL METHOD, AND ARTICLE MANUFACTURING METHOD

(71) Applicant: CANON KABUSHIKI KAISHA, Tokyo (JP)

(72) Inventor: NAOKI MURASATO, Tochigi (JP)

(21) Appl. No.: 18/166,991

(22) Filed: Feb. 9, 2023

(30) Foreign Application Priority Data
Feb. 15, 2022 (JP) 2022-021460
Oct. 24, 2022 (JP) 2022-170051

(51) Int. Cl. B29C 59/02

(52) U.S. Cl. CPC B29C 59/02

(57) ABSTRACT

In an imprint apparatus for forming a pattern of a curable composition on a substrate using a mold, an air flow is generated between a mold holding unit holding a member and the member to remove foreign particles, in a state where the member held by the mold holding unit is deformed in a direction perpendicular to a surface of the member.

### BACKGROUND OF THE INVENTION

### Field of the Invention

The present disclosure relates to an imprint apparatus, a foreign particle removal method, and an article manufacturing method.

### Description of the Related Art

Increased demands for miniaturization of a semiconductor device and a microelectromechanical system (MEMS) have drawn attraction to an imprint technique that can form a minute pattern (structure) of several nanometer order on a substrate, in addition to the conventional photolithographic technique. The imprint technique is a fine processing technique for forming a pattern of an imprint material corresponding to a minute convex-concave pattern formed on a mold by supplying (applying) an uncured imprint material on a substrate and bringing the imprint material and the mold (die) into contact with each other. In general, such a mold is sucked and held by a mold holding unit (mold chuck), as discussed in Japanese Unexamined Patent Application Publication (Translation of PCT Application) No. 2008-504141.

In such an imprint apparatus, if foreign particles such as dusts adhere between a mold holding unit and a mold, there is a concern that scratches may form on the back side of the mold by the foreign particles, or the mold holding unit cannot hold the mold due to the decrease of suction pressure.

Until now, in a case where foreign particles are found, it was necessary to dismount the mold once from the mold holding unit to perform cleaning processing for removing the foreign particles. Thus, it was not easy to remove the foreign particles, and the apparatus operating rate was caused to decrease.

### SUMMARY OF THE INVENTION

The present disclosure is directed to, for example, an imprint apparatus including a mechanism capable of easily removing foreign particles present between a mold and a mold holding unit.

According to an aspect of the present disclosure, an imprint apparatus configured to perform imprint processing of forming a pattern of a curable composition on a substrate using a mold includes a mold holding unit configured to hold the mold, and a control unit configured to perform control, in a state where a member held by the mold holding unit is deformed in a direction perpendicular to a surface of the member, to generate an air flow between the mold holding unit and the member to remove a foreign particle.

According to another aspect of the present disclosure, an imprint apparatus configured to perform imprint processing of forming a pattern of a curable composition on a substrate using a mold includes a mold holding unit configured to hold the mold, and a control unit configured to perform control, in a state where at least a part of a member held by a conveyance unit is separate from the mold holding unit, to generate an air flow between the mold holding unit and the member to remove a foreign particle.

Further features of the present disclosure will become apparent from the following description of exemplary embodiments with reference to the attached drawings.

### BRIEF DESCRIPTION OF THE DRAWINGS

FIG. 1 is a diagram schematically illustrating an imprint apparatus according to an exemplary embodiment of the present disclosure.

FIG. 2A is a side view illustrating a configuration of a mold holding unit of the imprint apparatus, and FIG. 2B is a diagram illustrating the mold holding unit viewed from the bottom side thereof.

FIG. 3 is a flowchart illustrating foreign particle removal processing.

FIG. 4A is a diagram illustrating first foreign particle removal processing, and FIG. 4B is a diagram illustrating second foreign particle removal processing.

FIG. 5A is a diagram illustrating the first foreign particle removal processing, and FIG. 5B is a diagram illustrating the second foreign particle removal processing.

FIG. 6 is a diagram illustrating a method of improving a foreign particle removal efficiency using inactive gas or a charge removal unit when foreign particle removal processing is performed.

FIG. 7 is a side view illustrating a configuration of a mold holding unit of an imprint apparatus.

FIG. 8 is a flowchart illustrating foreign particle removal processing.

FIGS. 9A and 9B are diagrams illustrating conventional foreign particle removal processing.

FIGS. 10A to 10F are diagrams illustrating an article manufacturing method.

FIG. 11 is a diagram illustrating foreign particle removal processing.

FIG. 12 is a diagram illustrating the mold holding unit viewed from the bottom side thereof.

### DESCRIPTION OF THE EMBODIMENTS

Hereinbelow, exemplary embodiments of the present disclosure will be described with reference to the attached drawings. In the drawings, the same reference numerals are assigned to the same members, and duplicate descriptions thereof are omitted.

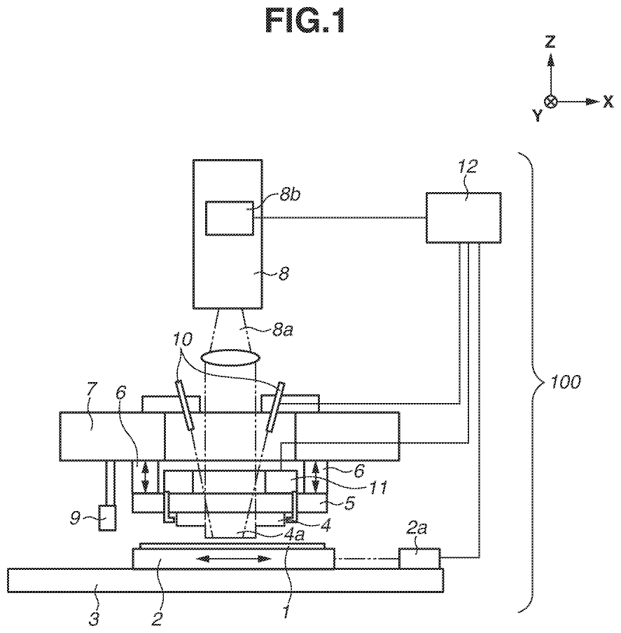

Now, a first exemplary embodiment will be described. FIG. 1 is a diagram schematically illustrating a configuration of an imprint apparatus 100 as an aspect of the present disclosure.

In FIG. 1, an X-axis, a Y-axis, and a Z-axis are defined in three axial directions orthogonal to each other.

The imprint apparatus 100 is a lithography apparatus used in a manufacturing process of semiconductor devices or the like, and configured to form patterns in a plurality of shot areas of a substrate by repeating an imprint processing cycle. The imprint apparatus 100 cures an imprint material (curable composition) in a state where a mold with a pattern formed thereon and the imprint material supplied (applied) onto a substrate are in contact with each other, and then separates the mold from the cured imprint material to transfer the pattern onto the substrate.

More specifically, the imprint processing performed on each shot area of the substrate includes supply processing, mold pressing processing, cure processing, and mold release processing. The supply processing is processing of supplying an imprint material onto the substrate. The mold pressing processing is processing of bringing the mold and the imprint material on the substrate into contact with each other. By bringing the mold and the imprint material on the substrate into contact with each other, i.e., pressing the mold to the imprint material, the imprint material is filled in a pattern area (concave portions of the pattern) of the mold. The cure processing is processing of curing the imprint material in a state where the mold and the imprint material on the substrate are in contact with each other. The mold release processing is processing of releasing the mold from the cured imprint material on the substrate.

As illustrated in FIG. 1, the imprint apparatus 100 includes a mold holding unit (mold chuck) 5 for sucking and holding a mold 4, a substrate stage 2 for sucking and holding a substrate 1 to fix it, a curing unit 8, a base frame 3, a dispenser 9 (discharge portion), and a control unit 12.

Further, the imprint apparatus 100 includes scopes 10 and a mold shape correction unit 11.

The substrate stage 2 can move the substrate 1 in XY directions and rotational directions in an XY plane to position the substrate 1, and change a portion (shot area) of the substrate 1 facing the mold 4 held by the mold holding unit 5. The substrate stage 2 is provided with a displacement sensor 2a for detecting the displacement position of the substrate stage 2, and drives and moves the substrate stage 2 with a motor based on a detected value of the displacement sensor 2a, to an exact position. As the displacement sensor 2a, a laser interferometer or an encoder can be used, for example. The base frame 3 guides and holds the substrate stage 2.

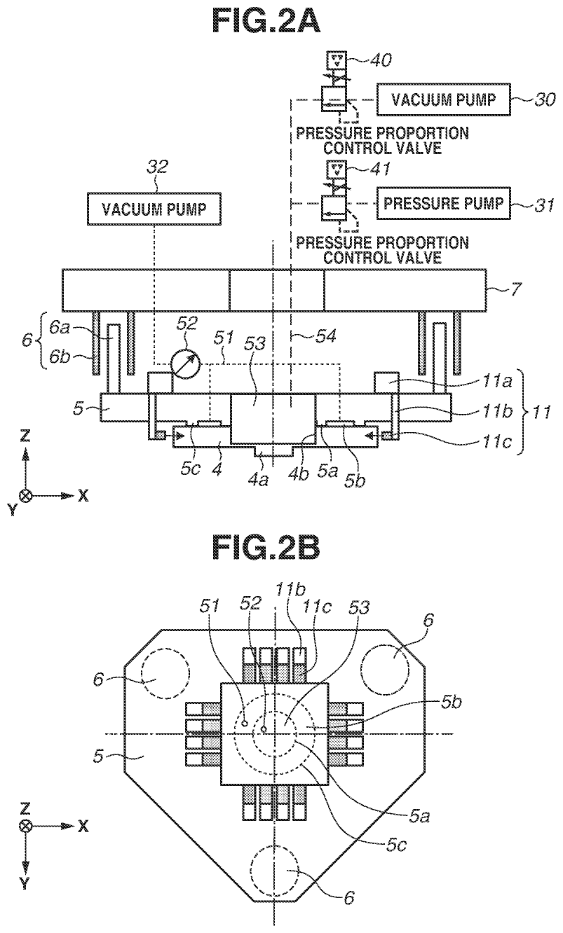

The mold 4 has a concave-convex pattern structure on the surface of a mesa portion 4a of the mold 4, and in addition, has a step structure protruding from a mold base material to prevent areas other than the mesa portion 4a from contacting the substrate 1. Further, on the opposite side surface of the mesa portion 4a, a recessed portion 4b (see FIG. 2A) is provided so that the mesa portion 4a can be deformed easily. In this way, the thickness of the mold 4 in the area where the mesa portion 4a is provided is made thin, and the pattern shape on the mesa portion 4a can be deformed easily.

Drive units 6 for performing up-and-down drive are connected to the mold holding unit 5 for holding the mold 4. The drive units 6 are fixed to a surface table 7 of the main body of the imprint apparatus 100, and performs operation to press the mold 4 to the uncured curable composition on the substrate 1. Metals, silicon (Si), various kinds of resins, and various kinds of ceramics can be used as a material of the mold 4. However, in a case where a photo-setting resin material is used as the imprint material, a light-transparent material such as quartz, sapphire, and transparent resin is used.

The curing unit 8 cures the curable composition supplied on the substrate 1. The curing unit 8 has a configuration that can cure the curable composition according to the types thereof. For example, if the curable composition is a photo-setting resin material, the curing unit 8 is configured of a light irradiation mechanism for irradiating the curable composition on the substrate 1 with light, specifically, light with a wavelength in ultraviolet light range (UV light) in general. If the curable composition is a thermosetting resin material, the curing unit 8 is configured of a heating mechanism for heating the curable composition on the substrate 1. In the present exemplary embodiment, a description is given using an example of a photo-setting curable composition.

The curing unit 8 functioning as a UV irradiation unit irradiates the curable composition with curing light such as UV light 8a that has transmitted through the mold 4 to cure the curable composition. The curing unit 8 includes a shutter unit 8b for controlling irradiation timing.

The curable composition needs to have a flow property when filled in the pattern of the mold 4, and needs to be solid property to keep the shape after the imprint processing. For this reason, photo-setting resin materials, thermosetting resin materials, and thermoplastic resin materials are used for the curable composition. In particular, the photo-setting resin materials are suitable for manufacturing the semiconductor devices, because temperature change is not necessary in the curing process, and thus changes in position and shape of the pattern formed on the substrate 1 caused by thermal expansion and thermal contraction of the materials of the mold 4, the substrate 1, and members of the imprint apparatus 100 are small.

The curable composition may be supplied (applied) on the substrate 1 in advance using a spin coat method, a slit coat method, a screen printing method, or the like, or may be supplied on the substrate 1 in the imprint apparatus 100 using the dispenser 9 that employs, for example, a pneumatic method, a mechanical method, or an inkjet method.

The method of applying the curable composition by the dispenser 9 can enhance the accuracy of residual layer thickness of the curable composition formed on the substrate 1, because the supply amount of the curable composition to be supplied onto the substrate 1 can be adjusted locally in accordance with the density of the patterns of the mold 4. Further, since the processes from when the curable composition is supplied onto the substrate 1 to when the mold 4 is brought into contact with the curable composition can be performed in a short time, the filling time of the curable composition can be reduced by selecting a material with high volatility and low-viscosity. Thus, it is advantageous for manufacturing semiconductor devices that call for high precision and high throughput.

In the case of applying the curable composition using the dispenser 9, the curable composition can be applied by moving the substrate 1 under the dispenser 9.

A material suitable for a usage after processing is selected for the substrate 1. For example, as a material for the substrate 1, silicon (Si) is used for a usage as a semiconductor device, quartz, optical glass, or transparent resin is used for a usage as an optical element, and gallium nitride (GaN) or silicon carbide (SiC) is used for a usage as a light emitting element.

Each of the scopes 10 includes an optical lens, an illumination, and an image detection sensor therein to detect the relative positional displacement between the mold 4 and an alignment mark on the substrate 1. An alignment between the mold 4 and the substrate 1 can be performed by making a minute movement of the substrate stage 2 to perform position correction, based on the displacement amount.

The mold shape correction unit 11 is mounted on the mold holding unit 5. The mold shape can be changed by applying pressures on the sides of the mold 4. In this way, a pattern shape provided on the mesa portion 4a of the mold 4 can be corrected to deform the pattern shape in a desired shape.

The control unit 12 includes a central processing unit (CPU) and a memory, and can perform various controls of the imprint processing by controlling the components of the imprint apparatus 100. Further, the control unit 12 can perform calculation based on alignment information obtained by the scopes 10, position information of the substrate stage 2, information about a load applied by the mold shape correction unit 11 to perform most appropriate alignment control.

The configuration of the imprint apparatus 100 is not limited to the configuration illustrated in FIG. 1, as long as the functions described above are satisfied. For example, when the mold 4 and the substrate 1 are brought into contact with each other via the curable composition, the mold 4 or both of the substrate 1 and the mold 4 may be moved instead of moving only the substrate 1. Further, the curing unit 8 may be disposed on the substrate 1 side not on the mold 4 side.

Next, with reference to FIGS. 2A and 2B, a configuration of the mold holding unit 5 of the imprint apparatus 100 will be described in detail. FIG. 2A is a diagram illustrating the imprint apparatus 100 viewed from a side (Y-axis direction) thereof, and FIG. 2B is a diagram illustrating the mold holding unit 5 of the imprint apparatus 100 viewed from the bottom side (Z-axis direction) thereof. The mold 4 is supported by a first protruding portion 5a and a second protruding portion 5c provided on the mold holding unit 5. As seen from FIG. 2B, each of the first protruding portion 5a and the second protruding portion 5c is formed in an annular shape to contact the back surface of the mold 4.

The mold 4 is sucked and held by the mold holding unit 5 by performing vacuum suction on an area 5b surrounded by the first protruding portion 5a and the second protruding portion 5c through an opening of a pipe 51 on the surface of the mold holding unit 5 side by a vacuum pump 32 serving as a vacuum source.

A flowmeter 52 is provided in a path of the pipe 51 to measure a flow rate of gas flowing in the pipe 51. In addition, as the vacuum source, a different type vacuum source such as an ejector may be used.

A pipe 54 is connected to a space area 53 surrounded by the mold holding unit 5 and the recessed portion 4b provided on the back surface of the mesa portion 4a of the mold 4, to pressurize or depressurize the space area 53. The pipe 54 is bifurcated into two pipes and connected to a vacuum pump 30 serving as a vacuum source and a pressure pump 31 serving as a pressure source, and a pressure proportion control valve 40 and a pressure proportion control valve 41 are provided in the middle of respective pipes to control the pressure. With this configuration, the space area 53 can be made to be a desired pressure such as a positive pressure and a negative pressure. Further, to control the pressure accurately, a pressure sensor (not illustrated) may be provided near the space area 53.

The mold shape correction unit 11 includes drive units 11a, drive transmission units 11b, and load cell units 11c, and can deform the mold shape by applying a desired force to each side surface of the mold 4. Further, the mold shape correction unit 11 is configured to be able to vertically adjust positions of side surfaces of the mold 4 at which the mold is pressed to the substrate 1.

The mold holding unit 5 and the surface table 7 of the main body are held via the drive units 6. Each of the drive units 6 includes a movable portion 6a and a fixed portion 6b. More specifically, a voice coil motor or a linear shaft motor can be used. These motors are advantageous in terms of the generation risk of foreign particles because they have no frictional portions, but other drive sources including frictional portions, such as a ball screw rotary motor, an air cylinder, and a piezoelectric element actuator, may be used if measures against attraction of foreign-substances or the like are taken. Each of the drive units 6 further includes a guide or a spring for supporting or restricting the movement direction of the mold pressing drive.

The mold holding unit 5 includes three drive units 6 serving as mold pressing sources, as seen in FIG. 2B, and the mold 4 is sucked and held at the center of the mold holding unit 5. Further, a plurality of the drive transmission units 11b and a plurality of the load cell units 11c of the mold shape correction unit 11 are provided to contact the corresponding end surfaces of the mold 4.

In the imprint apparatus 100 according to the present exemplary embodiment described with reference to FIGS. 1, 2A, and 2B, the mold 4 is held without falling down from the mold holding unit 5 by the vacuum pressure applied via the pipe 51, and the value indicated by the flowmeter 52 in the held state is ideally 0 L/min, which means no flow.

However, the first protruding portion 5a and the second protruding portion 5c of the mold holding unit 5 are not necessarily in contact with the mold 4 without gap due to the roughness of the surface or the error of the flatness. For this reason, even in a state where the mold 4 is sucked and held properly, the flowmeter 52 detects a small flow rate such as 0.3 L/min or less. Further, in a case where the foreign particles present in the neighboring space or the surfaces of the members are sandwiched between the mold 4 and the first protruding portion 5a or the second protruding portion 5c, the leak of air becomes noticeable and the flowmeter 52 detects a large flow rate such as 0.5 L/min or more.

Thus, since the degree of vacuum reduces by inclusion of the foreign particles between the mold 4 and the first protruding portion 5a or the second protruding portion 5c, there may be a concern that a sufficient suction pressure to hold the mold 4 cannot be secured, and the mold 4 cannot be held any more. Further, there may be a concern that the back surface of the mold 4 is damaged by deforming the mold shape by the mold shape correction unit 11 in the state where the foreign particles are present.

To solve such concerns that may occur in the case where the foreign particles are present, it is conventionally necessary to stop the operation of the imprint apparatus 100, and once demount the mold 4 from the mold holding unit 5 to perform processing for removing the foreign particles.

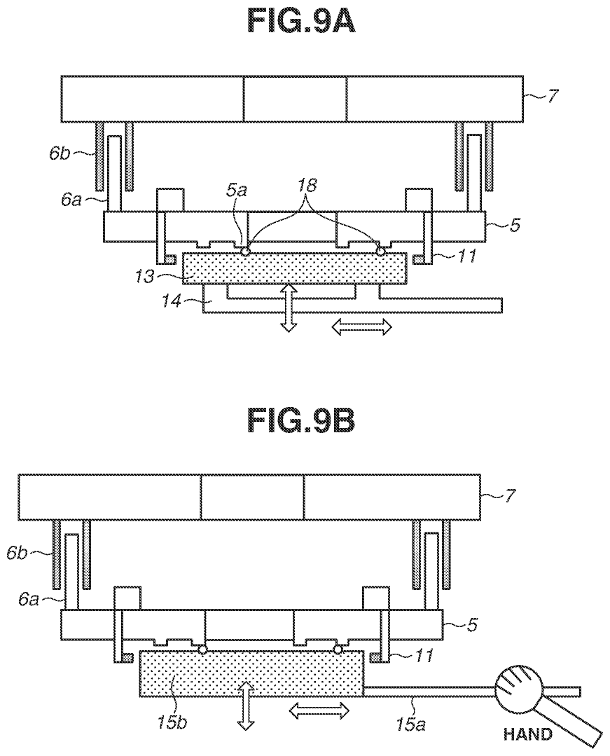

FIGS. 9A and 9B are diagrams illustrating conventional foreign particle removal processing. In FIGS. 9A and 9B, the pipes and sensors are omitted. In FIGS. 9A and 9B, a state where foreign particles 18 are present on the surface of the first protruding portion 5a is illustrated as an example. The sizes of foreign particles commonly seen in the imprint apparatus 100 are approximately 100 nm at minimum, and approximately 300 μm at maximum. The method of the foreign particle removal processing illustrated in FIG. 9A uses a tool 13 held by a mold conveyance hand 14 to remove the foreign particles. The surface of the tool 13 is made of an adhesive material, and is brought into contact with the first protruding portion 5a and the second protruding portion 5c to cause the foreign particles 18 to adhere to the tool 13 side. In this way, the foreign particles 18 are removed from the first protruding portion 5a. The method of the foreign particle removal processing illustrated in FIG. 9B is an example in which an operator holds a handle 15a of a removal tool to remove the foreign particles 18. A leading edge portion 15b of the removal tool is made of an adhesive material or a sponge containing solvent, and the leading edge portion 15b is brought into contact with the first protruding portion 5a or the second protruding portion 5c to cause the foreign particles 18 to adhere to the removal tool side. In this way, the foreign particles 18 are removed from the first protruding portion 5a.

With the conventionally performed foreign particle removal methods, the foreign particles cannot be removed in a short time, so that the apparatus operation rate deteriorates. Hereinbelow, a foreign particle removal method according to the present exemplary embodiment will be described in detail.

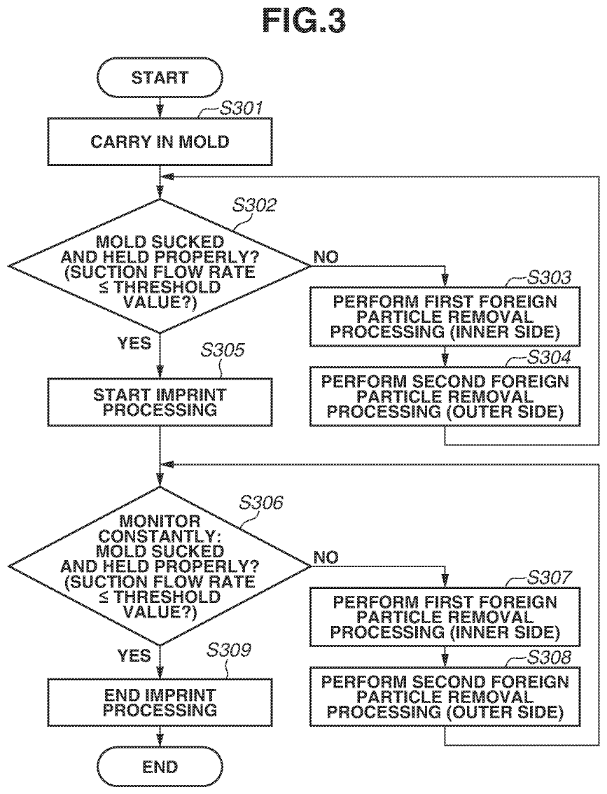

FIG. 3 is a flowchart illustrating foreign particle removal processing according to the present exemplary embodiment. The processing illustrated in FIG. 3 is implemented by the control unit 12 controlling the components of the imprint apparatus 100. In addition, the example of the flowchart in FIG. 3 is described using an example in which the foreign particle removal processing is performed immediately before the imprint processing and during the imprint processing, but the foreign particle removal processing described below may be performed at a desired timing as appropriate. Further, in a case where the foreign particle removal processing is performed at a timing other than immediately before the imprint processing and during the imprint processing, the mold holding unit 5 may hold a member other than the mold 4 with a pattern to perform the foreign particle removal processing. Such a member only needs to be conveyable by the mold conveyance hand 14 like the mold 4 and deformable by applying pressure.

In step S301, when the imprint apparatus 100 starts operating, the control unit 12 carries the mold 4 in the mold holding unit 5 by the mold conveyance hand 14 (conveyance unit). Then, the control unit 12 brings the mold 4 into contact with the mold holding unit 5, to be held by applying a vacuum pressure to the pipe 51

In step S302, the control unit 12 measures a flow rate in the pipe 51 using the flowmeter 52, to determine whether the mold 4 is sucked and held properly without inclusion of foreign particles between the mold 4 and the mold holding unit 5. More specifically, the control unit 12 checks whether a suction flow rate measured by the flowmeter 52 is a predetermined threshold value or less. In a case where the suction flow rate is the predetermined threshold value or less, the control unit 12 determines that the mold 4 is correctly sucked and held without inclusion of the foreign particles therebetween (YES in step S302), and the processing proceeds to step S305. On the other hand, in a case where the suction flow rate is greater than the predetermined threshold value, the control unit 12 determines that the foreign particles are present (NO in step S302) because there is a possibility that the mold 4 is not properly sucked and held due to the influence of the foreign particles, and the processing proceeds to step S303. In step S303, the control unit 12 performs the foreign particle removal processing.

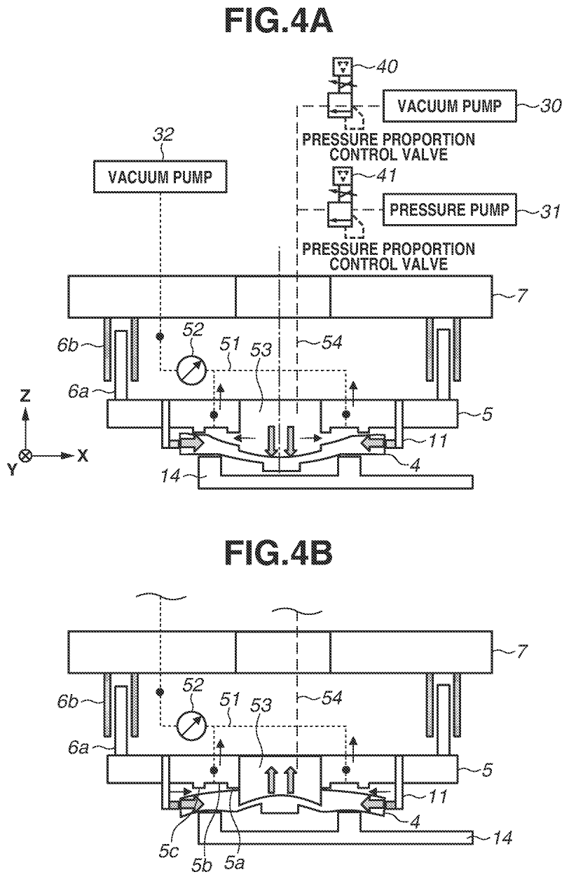

In steps S303 and S304, the control unit 12 sequentially performs first foreign particle removal processing (inner side) illustrated in FIG. 4A, and second foreign particle removal processing (outer side) illustrated in FIG. 4B, to remove the foreign particles.

In the present exemplary embodiment, the example of performing the foreign particle removal processing on the inner side and next on the outer side will be described, but may be performed in reverse order.

The first foreign particle removal processing is performed in a state (first deformation state) where the mold 4 is deformed convexly toward the substrate 1 in a direction perpendicular to the mold surface (Z-axis downward direction) as illustrated in FIG. 4A. Then, the second foreign particle removal processing is performed in a state (second deformation state) where the mold 4 is deformed concavely toward the substrate 1 in a direction perpendicular to the mold surface (Z-axis upward direction), which is the direction opposite to the direction in which the first foreign particle removal processing is performed, as illustrated in FIG. 4B. Further, the foreign particle removal processing can be performed in a state where the mold 4 used in the imprint processing is held, but the foreign particle removal processing may also be performed after replacing the mold 4 having a pattern with a mold dedicated to the foreign particle removal.

With reference to FIG. 4A, the first foreign particle removal processing (inner side) will be described in detail. The mold 4 is deformed convexly downward, which is a direction perpendicular to the surface of the mold 4, by pressurizing the space area 53 with the pressure pump 31 via the pipe 54. At the same time, since the area 5b is sucked by the vacuum pump 32 connected to the pipe 51, the mold 4 is continuously held by the mold holding unit 5. In other words, by controlling the balance between the pressurization by the pressure pump 31 and the vacuum suction by the vacuum pump 32, the mold 4 is held by the mold holding unit 5 while being deformed convexly downward.

By deforming the shape of the mold 4 in this way, a gap is generated between the back surface of the mold 4 and the first protruding portion 5a. At this time, since a gas flow is generated in a direction from the space area 53 to the pipe 51, the foreign particles are carried away by the gas flow and removed, in the case where the foreign particles are included between the first protruding portion 5a and the back surface of the mold 4. The size of the gap generated by the deformation of the mold 4 falls within approximately several micro-meters to 100 micro-meters, and thus the foreign particles with the sizes described above can be removed.

Further, the mold 4 can be deformed convexly downward with only the pressurization of the space area 53 by the pressure pump 31 as described above, but may be replaced or used together with the mold shape correction unit 11. More specifically, by the mold shape correction unit 11 applying the forces on the respective sides of the mold 4, the deformation convexly downward can be made larger. In addition, when the deformation is made convexly downward, it is preferable to apply the forces respectively to the upper sides of the end surfaces of the mold 4 by the mold shape correction unit 11.

Next, with reference to FIG. 4B, the second foreign particle removal processing (outer side) will be described in detail. In FIG. 4B, the mold 4 is deformed convexly upward, which is a direction perpendicular to the surface of the mold 4, by the vacuum suction of the space area 53 with the vacuum pump 30 via the pipe 54. At the same time, the vacuum pump 32 is sucking the area 5b to the vacuum via the pipe 51.

By deforming the shape of the mold 4 in this way, a gap is generated between the back surface of the mold 4 and the second protruding portion 5c. At this time, since a gas flow is generated in a direction from the outer side to the pipe 51, the foreign particles are carried away by the gas flow and removed, in a case where the foreign particles are included between the second protruding portion 5c and the back surface of the mold 4. The size of the gap generated by the deformation of the mold 4 falls within approximately several micro-meters to 100 micro-meters, and the foreign particles with the sizes described above can be removed.

Further, the mold 4 can be deformed convexly upward with only the vacuum suction of the space area 53 by the vacuum pump 30 as described above, but may be replaced or used together with the mold shape correction unit 11. More specifically, by the mold shape correction unit 11 applying the forces to the respective sides of the mold, the deformation convexly upward can be made larger. In addition, when the deformation is made convexly upward, it is preferable to apply forces respectively to the lower sides of the end surfaces of the mold 4 by the mold shape correction unit 11.

After completing the foreign particle removal processing in steps S303 and S304, the processing returns to step S302. In step S302, the control unit 12 checks again whether the mold 4 is sucked and held by the mold holding unit 5. In a case where the control unit 12 determines that the mold 4 is sucked and held by the mold holding unit 5 (YES in step S302), the processing proceeds to step S305. On the other hand, in a case where the control unit 12 determines that the mold 4 is not sucked and held by the mold holding unit 5 (NO in step S302), the processing proceeds to steps S303 and S304 to perform the foreign particle removal processing again. In this way, the foreign particle removal processing can be surely performed. Further, in a case where the mold 4 cannot be sucked and held properly even when the foreign particle removal processing is repeated a plurality of times, the control unit 12 may abort the processing as an error.

In step S305, the control unit 12 starts the imprint processing for each of a plurality of shot areas on the substrate 1. As illustrated in step S306, after the imprint processing, the control unit 12 constantly monitors the suction state of the mold holding unit 5 as in step S302. Then, in a case where the control unit 12 determines in step S306 that the suction is not performed properly (NO in step S306), the control unit 12 determines that the foreign particles are present, and tentatively stops the imprint processing, and then the processing proceeds to steps S307 and S308. In steps S307 and S308, the first foreign particle removal processing and the second foreign particle removal processing are performed. The processing performed in steps S306 to S308 is similar to that performed in steps S302 to S304, and descriptions thereof are omitted. Further, the foreign particle removal processing in steps S307 and S308 may preferably be performed before the imprint processing for a next shot area to be processed after the shot area on which the imprint processing is performed at a timing at which the abnormality is found.

In other words, the foreign particle removal processing is performed between the imprint processing for the shot area and the imprint processing for the next shot area.

After the foreign particle removal processing in steps S307 and S308, the processing returns to step S306. In step S306, the control unit 12 checks whether the mold 4 is sucked and held by the mold holding unit 5, and in a case where the control unit 12 determines that the mold 4 is sucked and held by the mold holding unit 5 (YES in step S306), the imprint processing is restarted. Further, in step S309, the processing is continued until the imprint processing for all the shot areas of the substrate 1 is completed.

According to the present exemplary embodiment described above, the foreign particle removal can be achieved without dismounting the mold 4 from the imprint apparatus 100 by performing the foreign particle removal processing on the back surface of the mold 4 in the case where the control unit 12 determines that the mold 4 is not sucked and held by the mold holding unit 5. Thus, the foreign particles can be removed simply, and the time taken for the foreign particle removal processing can be reduced.

Further, by performing the foreign particle removal processing in two steps (inner side and outer side), a fast air flow can be generated in a limited area even with a vacuum pressure ability of the same vacuum source, and a high foreign particle removal processing performance can be obtained. Further, since the removed foreign particles are sucked by the pipe 51 and not scattered within the apparatus, it is possible to reduce the possibility of contaminating other areas.

In addition, in the example illustrated in FIGS. 4A and 4B, the foreign particle removal processing is performed in the state where the mold 4 is supported by the mold conveyance hand 14 or the mold conveyance hand 14 is positioned under the mold 4. By performing the foreign particle removal processing in the state where the mold conveyance hand 14 is positioned under the mold 4, the mold conveyance hand 14 can function as a support when the mold 4 falls down. Further, in the state where the mold 4 is supported by the mold conveyance hand 14, i.e., at least one of the first protruding portion 5a and the second protruding portion 5c contacts or is located near the mold 4, the foreign particle removal processing can be performed even when the mold 4 is not sucked and held.

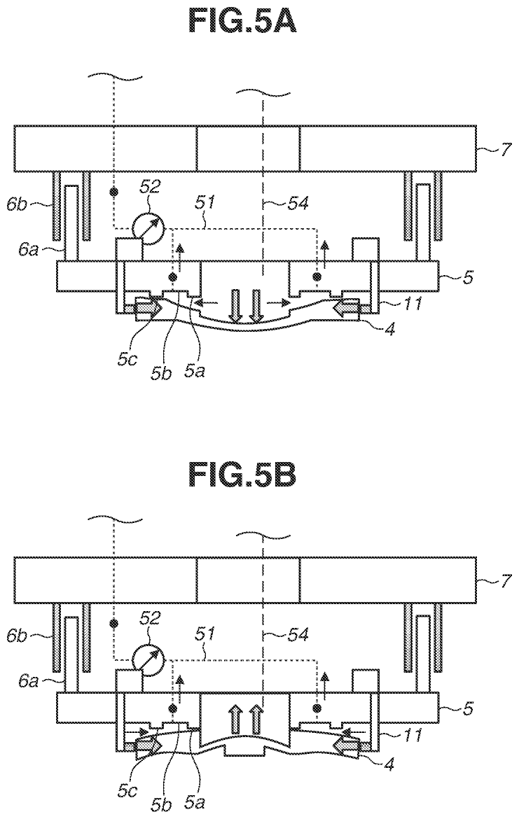

Further, the foreign particle removal processing can be performed in a state where the mold conveyance hand 14 is not provided as illustrated in FIGS. 5A and 5B. FIG. 5A is a diagram corresponding to the first foreign particle removal processing, and FIG. 5B is a diagram corresponding to the second foreign particle removal processing. In a case where the mold conveyance hand 14 is not used, to reduce the falling risk of the mold 4, the suction force of the vacuum pump 32 needs to be sufficiently larger than the pressurizing force applied to the space area 53 in the first foreign particle removal processing, in particular. It is possible to reduce time of the foreign particle removal process in the imprint process by not using the mold conveyance hand 14, and further reduce the decrease in productivity.

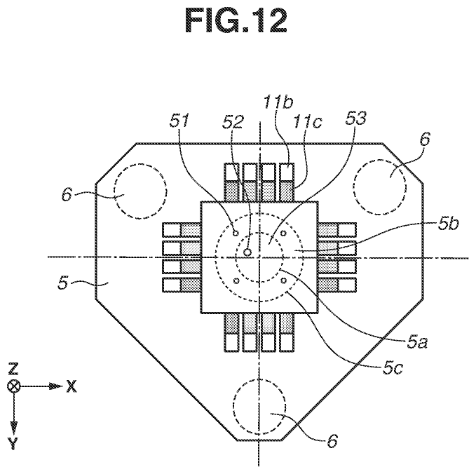

Openings of the pipe 51 provided on the mold holding unit 5 may be provided as illustrated in FIG. 12.

FIG. 12 is a diagram illustrating the mold holding unit 5 viewed from the bottom side thereof. A plurality of the openings of the pipe 51 may be provided in the area surrounded by the first protruding portion 5a and the second protruding portion 5c, and in the example illustrated in FIG. 12, four openings are provided at equal intervals on a circle. It is more advantageous for the foreign particle removal to generate an even air flow as much as possible in the circular area surrounded by the first protruding portion 5a and the second protruding portion 5c. For this reason, to reduce the flow rate distribution as much as possible, many openings of the pipe 51 may be provided as illustrated in FIG. 12.

In a second exemplary embodiment, a configuration to enhance the effect of the foreign particle removal processing described in the first exemplary embodiment will be described. Descriptions of components similar to those of the first exemplary embodiment are omitted.

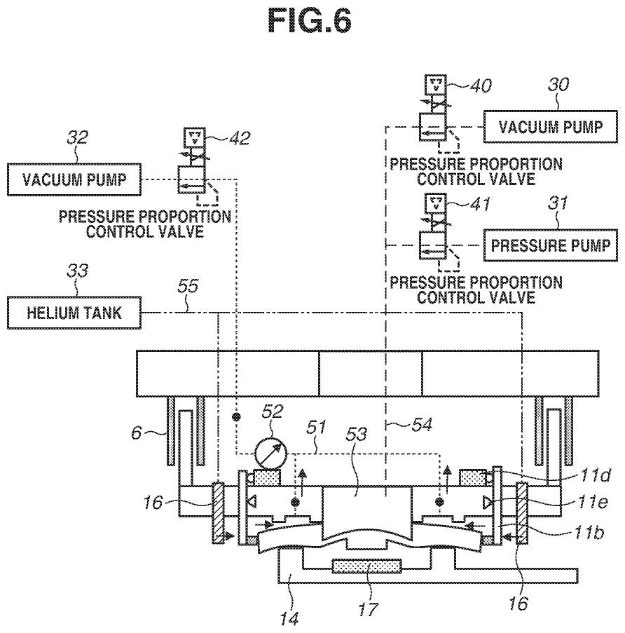

FIG. 6 is a diagram corresponding to the second foreign particle removal processing, and gas supply ports 16 (gas supply portions) for supplying inactive gas such as helium gas to the mold holding unit 5 are provided in addition to the configuration illustrated in FIG. 4B. A plurality of the gas supply ports 16 is provided on the side surfaces of the mold 4, and can blow the inactive gas toward the center of the mold 4.

Each of the gas supply ports 16 is connected to a helium (inactive gas) tank 33 via a pipe 55, and the gas supply can be controlled by an on/off switching valve (not illustrated) or a flow control valve provided in the middle of the pipe 55. By blowing the inactive gas such as helium gas during the foreign particle removal process, a charge removal effect can be obtained by the foreign particles in the mold surrounding space. The charged foreign particles stick to the surfaces of members and makes the foreign particle removal by the air flow difficult, but the charge removal effect by the inactive gas can eliminate or reduce the bad influence. In addition, since the inactive gas is supplied from the side surface sides of the mold 4, the inactive gas effectively acts at the time of the second foreign particle removal processing (outer side) illustrated in FIG. 6. For this reason, it is preferable to supply the inactive gas at least at the time of the second foreign particle removal processing.

Further, other methods for enhancing the effect of the foreign particle removal processing include a method of providing a charge removal unit 17 such as an ionizer on the mold conveyance hand 14. When the air in the ambient atmosphere is ionized by the ionizer, charges of the foreign particles in the charge removable area can be removed. Thus, by removing charges from the foreign particles on the first protruding portion 5a and the second protruding portion 5c by the ionizer, it is possible to enhance the foreign particle removal effect. The ionizer may desirably be provided near the mold 4 as much as possible, and thus to be provided on the mold conveyance hand 14. By providing the ionizer on the mold conveyance hand 14, the charge removal effect can be obtained not only by the foreign particles on the first protruding portion 5a and the second protruding portion 5c but also by the foreign particles on the pattern portion of the mold 4. The specific configuration of the charge removal unit 17 may desirably be selected from among methods such as an electric discharge method and an X-ray method, in consideration of the effectiveness, the size of the charge removal area, and the safety.

Further, to increase the effectiveness of the foreign particle removal processing, the use of the mold shape correction unit 11 may be conceivable. The mold shape correction unit 11 includes drive sources 11d for generating forces to be supplied to the respective end surfaces of the mold 4 on the mold holding unit 5, and drive transmission units 11b and fulcrums 11e for effectively transmitting the forces of the drive sources 11d to the mold 4. It is known that minute foreign particles are generally easy to adhere to the component surface due to the electric potential, surface roughness, and adhesiveness of the foreign particles themselves, and the foreign particles attached thereto separate from the attached state and float in the air if a cyclic vibration or a shock wave of gas is applied. More specifically, a cyclic vibration can be applied to the mold 4 by repeating the generation of large and small forces by the drive sources 11d of the mold shape correction unit 11. By performing such operation of the mold shape correction unit 11 at the time of the foreign particle removal processing, the removal efficiency of the foreign particles adhering to the back surface of the mold 4 can be improved.

Further, repeating the open/close operation of the pressure proportion control valve 42 in the pipe 51 while applying vacuum pressure through the pipe 51 causes a shock wave to transmit to the foreign particles through the gas, and can contribute to the foreign particle removal. Further, it is also possible to transmit the cyclic vibration to the foreign particles by the reciprocating motion of the drive units 6.

It is possible to achieve the foreign particle removal more efficiently by using the method for enhancing the effect of the foreign particle removal processing described above together with the foreign particle removal processing described according to the first exemplary embodiment.

In the first exemplary embodiment, the description is given of the method in which the first foreign particle removal processing and the second foreign particle removal processing are sequentially performed as the foreign particle removal processing. In a third exemplary embodiment, a description will be given of a method in which a position of a foreign particle is identified, and foreign particle removal processing corresponding to the identified position of the foreign particle is performed. In addition, the method for enhancing the effect of the foreign particle removal processing described in the second exemplary embodiment can be applied to the present exemplary embodiment. Hereinbelow, portions different from those of the first exemplary embodiment will be mainly described, and descriptions of similar portions will be omitted.

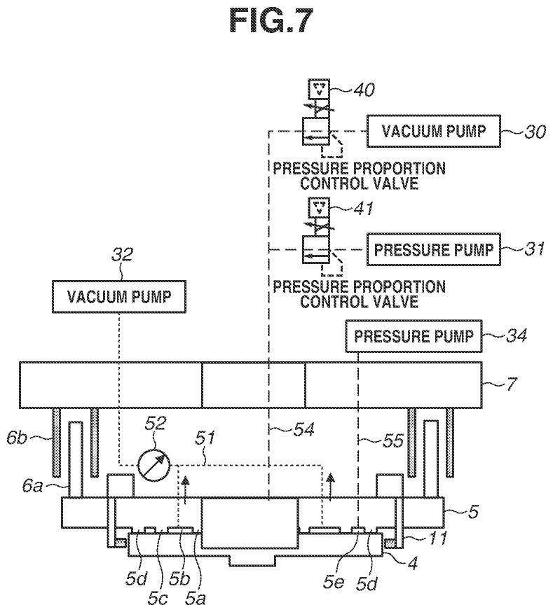

FIG. 7 is a side view illustrating a configuration of the mold holding unit 5 of the imprint apparatus 100 according to the present exemplary embodiment. Compared with the configuration illustrated in FIGS. 4A and 4B, a third protruding portion 5d is added on the outer side of the second protruding portion 5c. The third protruding portion 5d is formed in an annular shape so as to be able to support the mold 4 when the mold holding unit 5 of the imprint apparatus 100 is viewed from the bottom side (Z-axis direction) of the imprint apparatus 100.

Further, an area 5e surrounded by the third protruding portion 5d and the second protruding portion 5c can be pressurized by a pressure pump 34 through the pipe 55.

The control unit 12 can determine which position of the first protruding portion 5a and the second protruding portion 5c the foreign particle is on, by comparing and determining the flow rate measured by the flowmeter 52 when the area 5e is pressurized by the pressure pump 34 and that when the space area 53 is pressurized by the pressure pump 31. More specifically, in a case where the flow rate measured by the flowmeter 52 becomes larger when the area 5e is pressurized, the control unit 12 determines that the foreign particle is present between the first protruding portion 5a and the mold 4, and performs the first foreign particle removal processing. On the other hand, in a case where the flow rate measured by the flowmeter 52 becomes larger when the space area 53 is pressurized, the control unit 12 determines that the foreign particle is present between the second protruding portion 5c and the mold 4, and performs the second foreign particle removal processing.

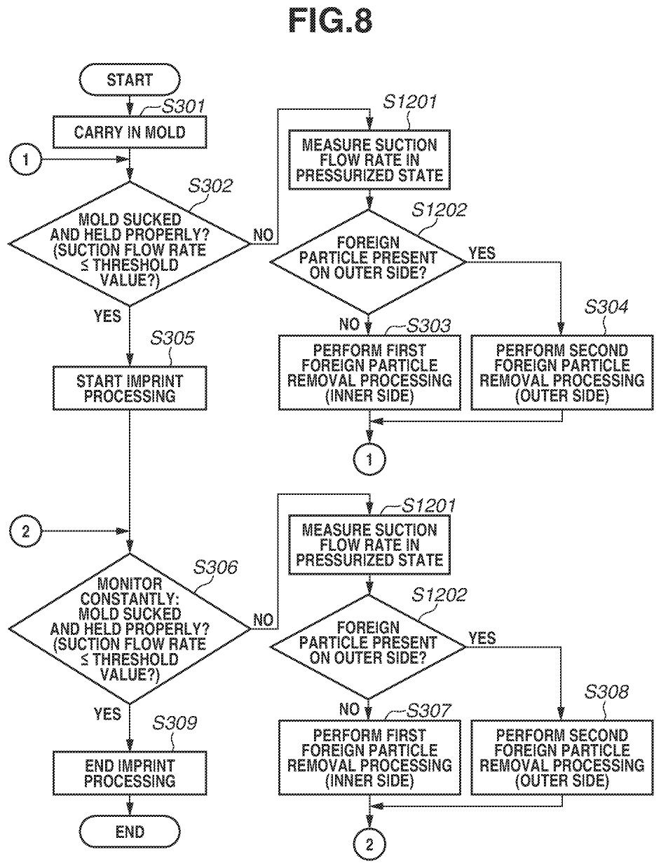

FIG. 8 is a flowchart illustrating foreign particle removal processing according to the present exemplary embodiment. The processing illustrated in FIG. 8 is implemented by the control unit 12 controlling the components of the imprint apparatus 100.

The processing performed in steps S301 and S302 is similar to that in FIG. 3, and thus descriptions thereof are omitted. In step S1201, the control unit 12 measures a flow rate by the flowmeter 52 when the space area 53 is pressurized, and a flow rate by the flowmeter 52 when the area 5e is pressurized.

In step S1202, the control unit 12 checks whether the foreign particle is present on the inner side or the outer side of the mold 4, i.e., whether the flow rate increases on the inner side or on the outer side of the mold 4. In step S1202, in a case where the control unit 12 determines that the foreign particle is present on the outer side of the mold 4 (YES is step S1202), the processing proceeds to step S304. In step S304, the control unit 12 performs the second foreign particle removal processing. On the other hand, in step S1202, in a case where the control unit 12 determines that the foreign particle is present on the inner side of the mold 4 (NO is step S1202), the processing proceeds to step S303. In step S303, the control unit 12 performs the first foreign particle removal processing. In addition, in a case where the control unit 12 determines that both of the flow rates are large in step S1201, the control unit 12 may sequentially perform both of the first foreign particle removal processing and the second foreign particle removal processing. The foreign particle removal processing performed after the start of the imprint processing is similar thereto, and thus a description thereof is omitted.

It is possible to further reduce the time taken for the simple foreign particle removal processing by identifying the position of the foreign particle and performing the foreign particle removal processing only for the identified position of the foreign particle, as in the present exemplary embodiment.

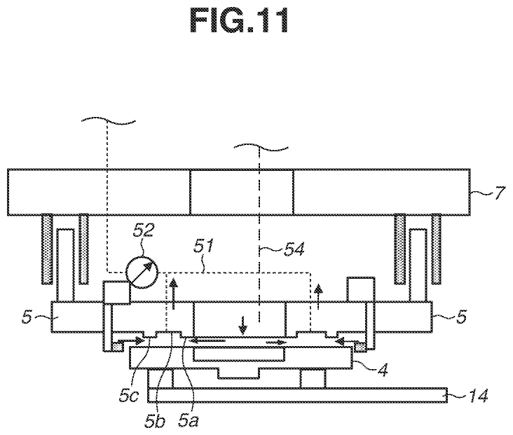

In a fourth exemplary embodiment, a description will be given of a method of performing the foreign particle removal processing in a state where the mold 4 is separate from the mold holding unit 5 without being sucked and held by the mold holding unit 5. FIG. 11 is a diagram illustrating foreign particle removal processing according to the present exemplary embodiment. The foreign particle removal processing is performed in a state where the mold 4 is held by the mold conveyance hand 14, and where the mold 4 and the first protruding portion 5a and the second protruding portion 5c of the mold holding unit 5 are positioned near.

At this time, the distance between the mold holding unit 5 and the mold 4 needs to be a distance in which the mold holding unit 5 does not contact the mold 4 even when a vacuum pressure is applied to the pipe 51, and the distance is desirably approximately 0.1 mm to 0.2 mm. Each of the first protruding portion 5a and the second protruding portion 5c is formed in an annular shape, and an opening of the pipe 51 is provided in the area surrounded by the first protruding portion 5a and the second protruding portion 5c. Then, by sucking the gas from via the opening of the pipe 51, the gas flows from the inner side of the first protruding portion 5a to the opening of the pipe 51, and from the outer side of the second protruding portion 5c to the opening of the pipe 51, at a time of the foreign particle removal processing. At this time, the state of the pipe 54 is desirably open to the atmospheric pressure not to stop the gas flow. Alternatively, it is preferable to apply pressure (supply gas) within a range of supplementing the air flow flowing toward the pipe 51.

The foreign particles can be removed by providing a certain gap between the mold holding unit 5 and the mold 4 to generate a constant flow speed on the back surface of the mold 4. In practice, even if the flow rate was relatively small such as 3 to 6 L/min, the foreign particles such as non-metal particles with relatively large size and relatively small specific gravity were able to be removed.

Further, it is possible to enhance the foreign particle removal effect by varying the flow speed rather than making the flow rate constant. For example, it is possible to vary the flow speed by connecting an open/close valve or a proportional valve to the pipe 51 or the pipe 54 and causing it to perform open/close operations at a certain cycle. Alternatively, it is possible to make the foreign particles easily movable by moving the mold holding unit 5 up and down using a Z drive mechanism of the imprint head to change the distance of the gap and varying the gas flow speed.

Further, the foreign particle removal processing may be performed in a state where a gap distance distribution is provided by providing a deformation device on the mold conveyance hand 14 to deform the mold 4 on the mold conveyance hand 14 as in the first exemplary embodiment, i.e., the mold 4 is deformed in a direction perpendicular to the mold surface. Further, the mold conveyance hand 14 may be provided with the charge removal unit 17 as in the second exemplary embodiment. The method of employing the mold conveyance hand 14 in this way takes time to operate each unit due to the sequence, but the mold deformation shape and the mold deformation amount can be set freely without caring the mold holding by the suction because there is no risk of the mold 4 falling on the wafer.

Further, also in the present exemplary embodiment, the foreign particle removal processing may be performed in a state where a member different from the mold 4 with the pattern is held by the mold holding unit 5.

### <Manufacturing Article>

The cured material pattern formed using the imprint apparatus 100 described above is used for at least a part of various articles permanently or used tentatively when the various articles are manufactured.

Examples of the articles include an electrical circuit element, an optical element, a microelectromechanical system (MEMS), a recording element, a sensor, and a mold. Examples of the electric circuit element include a volatile or nonvolatile semiconductor memory, such as a dynamic random access memory (DRAM), a static RAM (SRAM), a flash memory, and a magnetic RAM (MRAM), and a semiconductor device, such as a large-scale integration (LSI) device, a charge-coupled device (CCD), an image sensor, and a field programmable gate array (FPGA). Examples of the mold include a mold used for imprinting.

The cured pattern is directly used as a part of the component member of each of the above-described articles, or temporarily used as a resist mask. In the processing process of the substrate, after an etching or an ion implantation is performed, the resist mask is eliminated.

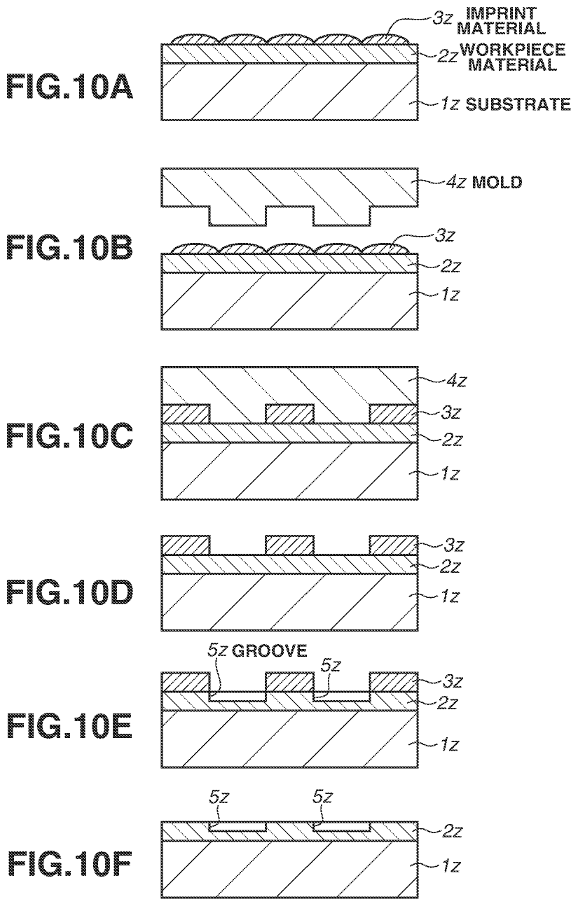

Next, with reference to FIGS. 10A to 10F, a description will be given of an article manufacturing method of forming a pattern on a substrate by the imprint apparatus 100, processing the substrate on which the pattern is formed, and manufacturing an article from the processed substrate. First, as illustrated in FIG. 10A, a substrate 1z such as a silicon wafer on a surface of which a workpiece material 2z such as an insulating material is formed is prepared, and next, an imprint material 3z is applied onto the surface of the workpiece material 2z using an ink jet method or the like. In the present exemplary embodiment, the imprint material 3z in a form of a plurality of droplets is applied onto the substrate 1z.

As illustrated in FIG. 10B, a mold 4z for the imprinting is set to face the imprint material 3z on the substrate 1z in a state where the side of the mold 4z with a concave/convex pastern formed thereon directing toward the imprint material 3z. As illustrated in FIG. 10C, the substrate 1z on which the imprint material 3z is applied and the mold 4z are brought into contact with each other to apply pressure. The imprint material 3z is filled in a gap between the mold 4z and the workpiece material 2z. When light serving as an energy for curing the imprint material 3z is radiated through the mold 4z in this state, the imprint material 3z is cured.

As illustrated in FIG. 10D, when the mold 4z is separated from the substrate 1z after the imprint material 3z is cured, a pattern of the cured material of the imprint material 3z is formed on the substrate 1z. This pattern of the cured material has a shape in which a convex portion of the cured imprint material 3z corresponds to a concave portion of the mold 4z, and a concave portion of the cured imprint material 3z corresponds to a convex portion of the mold 4z. In other words, the concave and convex pattern of the mold 4z is copied to the imprint material 3z.

As illustrated in FIG. 10E, when an etching is performed using the pattern of the cured imprint material 3z as an anti-etching mask, portions where no cured imprint material 3z or a thin cured imprint material 3z remains are removed from the surface of the workpiece material 2z to be grooves 5z. As illustrated in FIG. 10F, when the pattern of the cured imprint material 3z is removed, an article with the grooves 5z being formed on the surface of the workpiece material 2z can be obtained. In the present exemplary embodiment, the pattern of the cured imprint material 3z is removed, but the pattern of the cured imprint material 3z may be left after the process, and may be used, for example, as an interlayer insulation layer in the semiconductor device or the like, i.e., as a component member of the article.

Further, the article manufacturing method includes a process of forming a pattern on the imprint material 3z applied onto the substrate 1z using the above-described imprint apparatus 100 (imprint method), and a process of processing the substrate 1z on which the pattern is formed in the process. Further, the manufacturing method includes other known processes such as oxidization, film formation, vapor-deposition, doping, flattening, etching, resist removing, dicing, bonding, and packaging. The article manufacturing method according to the present exemplary embodiment is advantageous, compared with the conventional method, in at least one of performance, quality, productivity, and production cost, of the articles.

The exemplary embodiments according to the present disclosure have been described above, but the present disclosure is not limited to the exemplary embodiments, and can be modified and changed in various manners within the scope of the present disclosure.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2022-021460, filed Feb. 15, 2022, and No. 2022-170051, filed Oct. 24, 2022, which are hereby incorporated by reference herein in their entirety.

What is claimed is:

1. An imprint apparatus configured to perform imprint processing of forming a pattern of a curable composition on a substrate using a mold, the imprint apparatus comprising:
a mold holding unit configured to hold the mold; and
a control unit configured to perform control, in a state where a member held by the mold holding unit is deformed in a direction perpendicular to a surface of the member, to generate an air flow between the mold holding unit and the member to remove a foreign particle.

2. The imprint apparatus according to claim 1, wherein the control unit generates the air flow in a case where a space is generated between the mold holding unit and the member is sucked and held by the mold holding unit.

3. The imprint apparatus according to claim 1, wherein the member held by the mold holding unit is deformed by applying a force to an end surface of the member.

4. The imprint apparatus according to claim 1, wherein the member held by the mold holding unit is deformed by applying a pressure to a surface of the member opposite to a surface to contact the substrate.

5. The imprint apparatus according to claim 1, wherein the control unit generates the air flow in a first deformation state where the surface of the member becomes convex toward the substrate or in a second deformation state where the surface of the member becomes concave toward the substrate.

6. The imprint apparatus according to claim 1,
wherein the control unit determines a position at which the foreign particle is present between the mold holding unit and the member, and
wherein the control unit deforms the surface of the member based on the determined position of the foreign particle.

7. The imprint apparatus according to claim 1,
wherein the mold holding unit includes a first protruding portion and a second protruding portion, and
wherein the control unit generates the air flow between the mold holding unit and the member by depressurizing an area formed by the first protruding portion, the second protruding portion, and the member.

8. The imprint apparatus according to claim 7,
wherein each of the first protruding portion and the second protruding portion is formed in an annular shape, and
wherein the control unit generates the air flow by depressurizing the area formed by the first protruding portion, the second protruding portion, and the member via an opening provided in an area between the first protruding portion and the second protruding portion.

9. The imprint apparatus according to claim 1, further comprising a gas supply unit configured to supply inactive gas between the mold holding unit and the member,
wherein the control unit controls the gas supply unit so that the inactive gas is included in the air flow.

10. The imprint apparatus according to claim 1, further comprising a conveyance unit configured to convey the mold so that the mold is held by the mold holding unit,
wherein the control unit removes the foreign particle in a state where the conveyance unit is positioned under the member.

11. The imprint apparatus according to claim 10,
wherein the conveyance unit includes a charge removal unit, and
wherein the control unit performs control to generate the air flow in a state where the charge removal unit is removing charge.

12. The imprint apparatus according to claim 1,
wherein the imprint apparatus is an apparatus configured to sequentially perform the imprint processing for a plurality of shot areas on the substrate, and
wherein the control unit performs foreign particle removal processing by generating the air flow at a timing between imprint processing for a shot area and imprint processing for a next shot area.

13. An imprint apparatus configured to perform imprint processing of forming a pattern of a curable composition on a substrate using a mold, the imprint apparatus comprising:
a mold holding unit configured to hold the mold; and
a control unit configured to perform control, in a state where at least a part of a member held by a conveyance unit is separate from the mold holding unit, to generate an air flow between the mold holding unit and the member to remove a foreign particle.

14. The imprint apparatus according to claim 13, wherein the control unit performs control, in a state where the member held by the mold holding unit is deformed in a direction perpendicular to a surface of the member, to generate the air flow between the mold holding unit and the member.

15. The imprint apparatus according to claim 13,
wherein the mold holding unit includes a first protruding portion and a second protruding portion, and
wherein the control unit generates the air flow between the mold holding unit and the member by depressurizing an area formed by the first protruding portion, the second protruding portion, and the member.

16. The imprint apparatus according to claim 15,
wherein each of the first protruding portion and the second protruding portion is formed in an annular shape, and
wherein the control unit generates the air flow by depressurizing the area formed by the first protruding portion, the second protruding portion, and the member, via an opening provided in an area between the first protruding portion and the second protruding portion.

17. The imprint apparatus according to claim 13, wherein the conveyance unit conveys the mold so that the mold is held by the mold holding unit.

18. The imprint apparatus according to claim 13,
wherein the conveyance unit includes a charge removal unit, and
wherein the control unit performs control to generate the air flow in a state where the charge removal unit is removing charge.

19. A foreign particle removal method for an imprint apparatus configured to form a pattern of a curable composition on a substrate using a mold, the foreign particle removal method comprising:
deforming a member held by a mold holding unit in a direction perpendicular to a surface of the member; and
generating, in a state where the member is deformed, an air flow between the mold holding unit holding the member and the member.

20. A foreign particle removal method for an imprint apparatus configured to form a pattern of a curable composition on a substrate using a mold held by a mold holding unit, the foreign particle removal method comprising:
separating at least a part of a member held by a conveyance unit from the mold holding unit; and
generating, in a state where the at least a part of the member is separated from the mold holding unit, an air flow between the mold holding unit and the member.

21. An article manufacturing method comprising:
forming a pattern on a substrate using the imprint apparatus according to claim 1;
processing the substrate on which the pattern is formed; and
manufacturing an article using the processed substrate.
